(19) United States
(12) Patent Application Publication
(10) Pub. No.: US 2001/0045656 A1
(43) Pub. Date: Nov. 29, 2001

(54) Multilayer wiring structure for semiconductor device

(75) Inventor: Takashi Yokoyama, Tokyo (JP)

Correspondence Address: Norman P. Soloway, HAYES, SOLOWAY, HENNESSEY, GROSSMAN & HAGE, P.C., 175 Canal Street, Manchester, NH, 03101, US

(73) Assignee: NEC Corporation

(21) Appl. No.: 09/863,451

(22) Filed: May 22, 2001

(30) Foreign Application Priority Data
May 23, 2000 (JP) 151737/2000

(51) Int. Cl. H01L 23/48

(52) U.S. Cl. 257/758; 257/760

(57) ABSTRACT

The multilayer wiring structure for a semiconductor device according to the present invention is constituted by including a semiconductor substrate, a copper wiring covered with a diffusion preventive film, formed on the semiconductor substrate, a first layer insulating film formed on the semiconductor substrate and the copper wiring, a second layer insulating film with lower permittivity than that of the first layer insulating film formed on the first layer insulating film, a connection hole formed in the first layer insulating film and the second layer insulating film exposing the copper wiring to the hole, a groove formed in the second layer insulating film with its bottom making contact with the connection hole, a barrier metal layer formed on the side face of the connection hole and the groove, a copper via filling in the interior of the connection hole, and a copper groove wiring filling in the interior of the groove.

### BACKGROUND OF THE INVENTION

1. Field of the Invention

The present invention relates to a multilayer wiring structure for a semiconductor device, and more particularly to the structure of a multilayer wiring having copper (Cu) as its principal component.

2. Description of the Prior Art

Demand for faster signal processing in an LSI has been increasing year after year. The signal processing speed in an LSI is determined principally by the operating speed of a transistor itself and the magnitude of delay time of signal propagation in a wiring. In the past, the operating speed of a transistor that was dominantly affecting the above problem has been resolved by the reduction of the size of the transistor (namely, the increase in the operating speed of the transistor has been accomplished). However, in an LSI whose design rule is less than 0.18 μm, the latter-mentioned effect that relates to the delay of signal propagation in the wiring has been revealing itself significantly.

Under thee circumstances, an active development is being engaged in which metallic wiring layers are formed by using Cu that has a lower resistance than the conventionally used aluminum (Al). Besides, reduction in the delay of signal propagation is being attempted through the use of a material that has a smaller relative permittivity (dielectric constant) for a layer insulating film. For example, a wiring structure adopting a Hydrogen Silsesquioxane (HSQ) film having a relative permittivity of about 3.0 and a Cu wiring layer as a wiring structure applying a low permittivity film and Cu, as shown in FIG. 3 has been proposed. With this constitution, the delay in signal propagation can be reduced markedly.

However, since a film with low relative permittivity generally has a lower mechanical strength compared with a silicon oxide film, when a multilayer wiring is formed using such a low relative permittivity film, cracks or the like tend to be developed in the film. For this reason, when a multilayer is formed in the wiring section using an insulating film having a low relative permittivity for the purpose of reducing the delay in signal propagation, a structure that employs a silicon oxide film as the layer insulating film for a via section, aimed at securing mechanical strength, is expected to be promising (FIG. 4).

Referring to FIG. 5, a method of manufacture of such a structure will be described in the following. First, a SiN film 1202 for preventing diffusion of Cu, a silicon oxide film 1203 as a layer insulating film for a section where a metallic via is to be formed, a SiON film 1204 as a stopper film for stopping the formation by etching of a section for groove wiring, and a low permittivity film such as an HSQ film 1205 as a layer insulating film for the formation of an upper wiring layer, are formed in multilayer on a Cu wiring 1201 on a lower layer. Then, the multilayer is etched back to form the shape of a hole using a patterned photoresist 1206.

In this process, the etching must be stopped precisely at the SiN film 1202 (FIG. 5A). In order to work up a groove wiring form, after peeling the photoresist off, an antireflection coating (ARC) is applied filling in the hole section, photoresis is applied again patterned in the groove wiring form, and a groove section is formed by etching (FIG. 5B). Here, it is necessary to stop the groove etching when it proceeded to a certain level in the SiON film. Finally, the so-called dual damascene structure is completed by etching back the SiN film (FIG. 5C).

However, in the conventional example illustrated in FIG. 4, if films of SiN (with dielectric constant ε of 6 to 7) and SiON (ε of 5 to 6) with high relative permittivity are used below the groove for wiring, it is not possible, due to fringe effect, to effectively reduce the wiring capacitance even if a layer insulating film with low relative permittivity is used for the groove section. Moreover, in the etch back of the SiN film for the lower layer wiring, the groove section is also subjected to the etching, exposing the SiON film on the sidewall part of the groove section, obstructing further the reduction of the capacitance between the wirings.

### BRIEF SUMMARY OF THE INVENTION

### Object of the Invention

It is the object of the present invention to provide a multilayer wiring structure for a semiconductor device which is capable of reducing the capacitance between the wirings even if it is a structure that does not employ an etching stopper film such as a SiON film.

### Summary of the Invention

The multilayer wiring structure for a semiconductor device according to the present invention comprises a semiconductor substrate, a copper wiring covered with a diffusion preventive film, formed on the semiconductor substrate, a first layer insulating film formed on the semiconductor substrate and the copper wiring, a second layer insulating film having lower permittivity than that of the first layer insulating film formed on the first layer insulating film, a connection hole formed in the first layer insulating film and the second layer insulating film to which the copper wiring is exposed, a groove formed on the second layer insulating film with its bottom making contact with the connection hole, a barrier metal layer formed on the side faces of the connection hole and the groove, a copper via filling in the connection hole, and a copper groove wiring filling in the groove.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIGS. 1A to 1D are schematic block diagrams showing the manufacturing processes of a semiconductor device for the purpose of describing the embodiment according to the present invention;

FIG. 2 is a graph showing the dependence of the wiring capacitance on the location of the SiO₂ film;

FIG. 3 is a schematic block diagram showing a conventional example;

FIG. 4 is another schematic block diagram showing a conventional example; and

FIGS. 5A to 5C are schematic block diagrams showing the manufacturing processes of the conventional example.

### DETAILED DESCRIPTION OF THE INVENTION

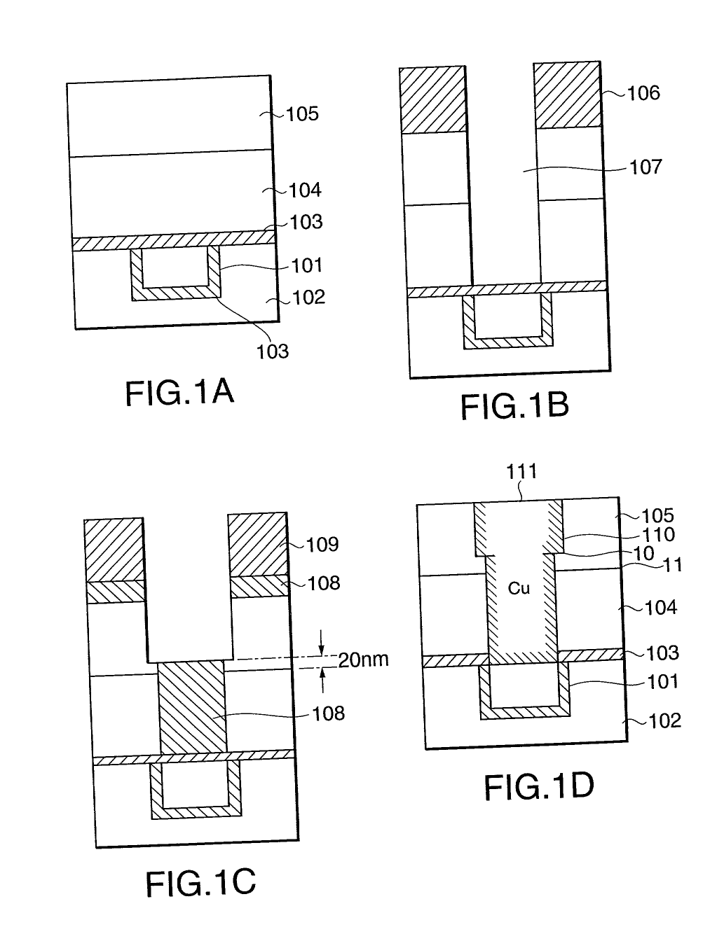

Referring to the drawings, a specific embodiment of the present invention will be described in the following. First, a method of manufacturing the semiconductor device of the invention will be described by reference to FIG. 1. Here, on a silicon substrate 102 with elements such as transistors formed thereon and having a first Cu wiring 101, a SiN film 103 with thickness of 10 to 100 nm as a Cu diffusion preventive film, a silicon oxide film or a fluorine containing silicon oxide film with thickness of 300 to 1000 nm as a layer insulating film 104 for the portion of formation of a metallic via section, and an HSQ film or a carbon containing silicon oxide film or an organic film or the like having a low permittivity as a layer insulating film 105 for the portion of formation of a second Cu wiring section, are formed as a multilayer (FIG. 1A).

Subsequently to that, a connection hole 107 with an upper layer wiring is opened by the known lithography and etching methods using a patterned photoresist 106 as a mask. In this process, the etching has to be stopped at the SiN film 103 without fail (FIG. 1B).

Next, after peeling the photoresist off, an ARC 108 is applied to the surface to fill in the hole section, then the multilayer is subjected to the coating of a second photoresist 109 for the formation of a groove wiring, and the photoresist is patterned. The ARC and the groove formation section are etched back with the photoresist as a mask to form the so-called dual damascene structure (FIG. 1C). Here, the bottom part of the groove is formed so as to be apart by more than 20 nm from the top surface of the layer insulating film 104 with higher relative permittivity where a metallic via section is to be formed.

Next, after the photoresist is peeled off and the SiN film 103 portion is etched back, a barrier metal 110 such as TaN is deposited on the surface of the hole by sputtering, Cu is filled in by sputtering and plating methods, and a groove wiring and a via, 111, are formed by chemical mechanical polishing (CMP) method (FIG. 1D).

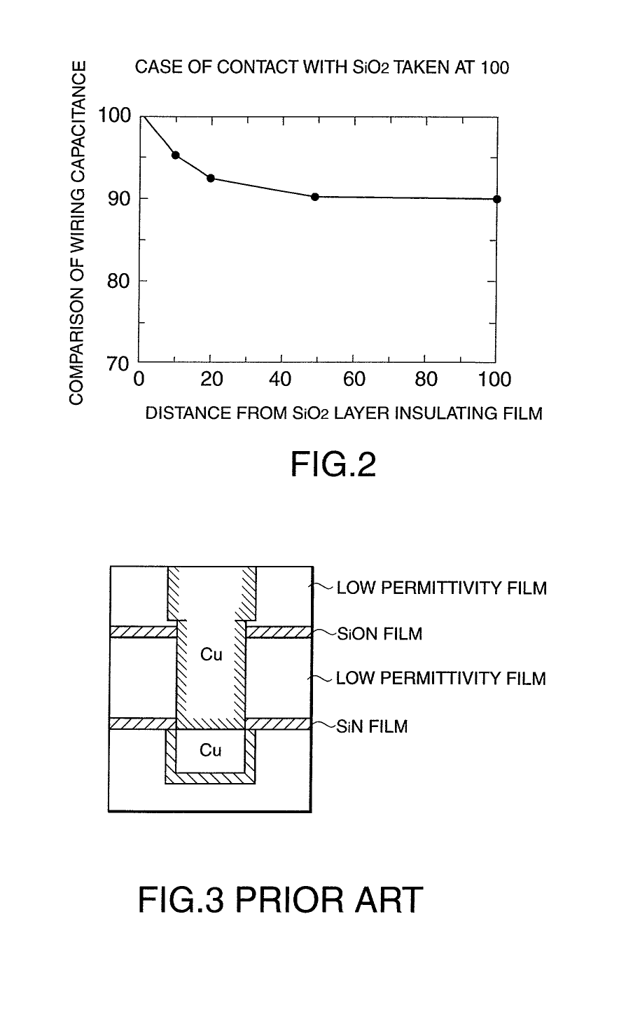

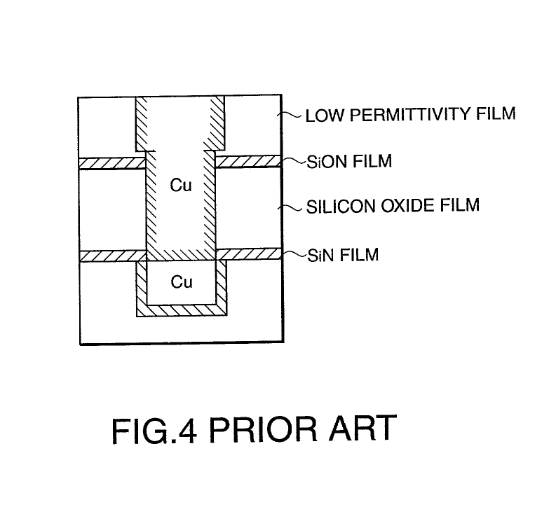

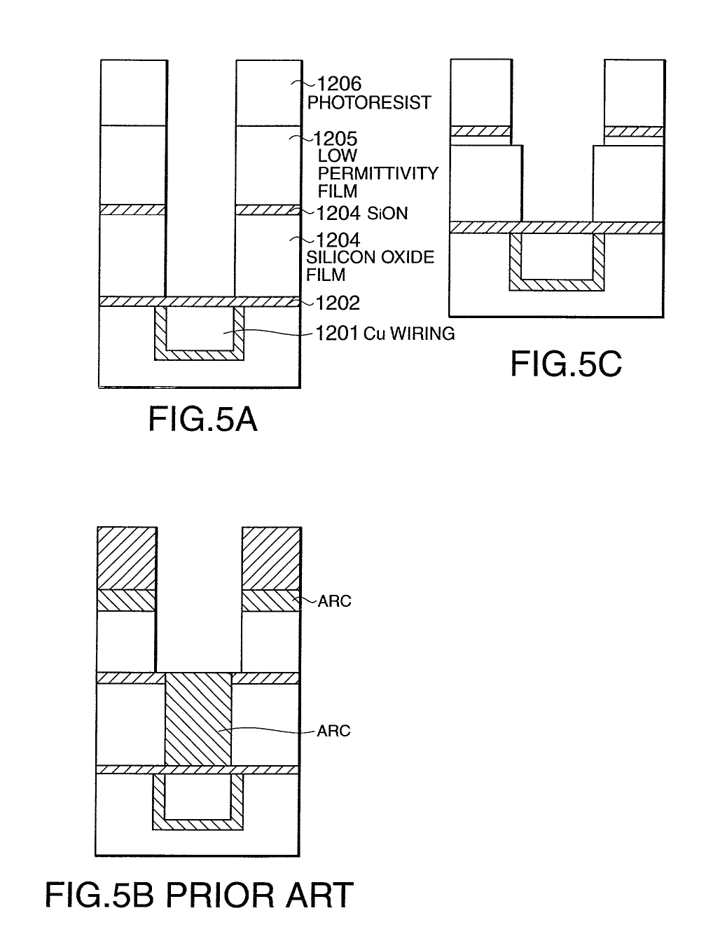

In a wiring structure constituted in this manner, when a silicon oxide film (ε≈4.2) and an HSQ film (ε≈3.0) are used as the layer insulating film 104 for the via section and as the layer insulating film 105 for the wiring section, respectively, in FIG. 1D, the dependence of the wiring capacitance on the distance between the bottom of the groove wiring section 10 and the top portion 11 of the layer insulating film for the metallic via section, decreases as the distance exceeds 20 nm as shown in FIG. 2, with the accompanying decrease in the fringe effect, so that it is possible to reduce the wiring capacitance. Moreover, an effective reduction in the wiring capacitance can be realized by eliminating the conventional use of such a material as SiON that has a high capacitance as an etching stopper beneath the groove wiring section.

As described in detail in the above, in the wiring structure for a semiconductor device having the so-called dual damascene structure, the present invention makes it possible to form a structure that is free from cracks and enables to reduce the wiring capacitance even when it is given a multilayer structure, by using a low capacitance layer insulating film for the wiring section and using a layer insulating film, with higher capacitance than that of the insulating film used for the wiring section, for the section of via formation. Moreover, by forming the bottom of the groove wiring section to be apart from the top surface of the layer insulating film for the via section by more than 20 nm, it is possible to obtain a structure that can reduce the influence of the fringe effect on the lower layer insulating film, and decrease the wiring capacitance.

Although the invention has been described with reference to a specific embodiment, this description is not meant to be construed in a limiting sense. Various modifications of the disclosed embodiment will become apparent to persons skilled in the art upon reference to the description of the invention. It is therefore contemplated that the appended claims will cover any modifications or embodiments as fall within the true scope of the invention.

What is claimed is:

1. A multilayer wiring structure for a semiconductor device comprising: a semiconductor substrate, a copper wiring covered with a diffusion preventive film, formed on said semiconductor substrate, a first layer insulating film formed on said semiconductor substrate and said copper wiring, a second layer insulating film having a lower permittivity than that of said first layer insulating film formed on said first layer insulating film, a connection hole formed in said first layer insulating film and said second layer insulating film with said copper wiring exposed to the hole, a groove formed in said second layer insulating film with its bottom making contact with said connection hole, a barrier metal layer formed on the side face of said connection hole and said groove, a copper via filling in the interior of said connection hole, and a copper groove wiring filling in the interior of said groove.

2. The multilayer wiring structure for a semiconductor device as claimed in claim 1, wherein the distance between the bottom of said groove and the top portion of said first layer insulating film is not less than 20 nm.

3. The multilayer insulating structure for a semiconductor device as claimed in claim 1, wherein said first layer insulating film is a silicon oxide film or a fluorine containing silicon oxide film and said second layer insulating film is a Hydrogen Silsesquioxane (HSQ) film or a carbon containing silicon oxide film or an organic film.
